(19) United States
(12) Patent Application Publication
(10) Pub. No.: US 2026/0071922 A1
(43) Pub. Date: Mar. 12, 2026

(54) SYSTEMS AND METHODS FOR IDENTIFYING A DIRECTION OF A SURFACE ACOUSTIC WAVE USING RESONATORS

(71) Applicant: Toyota Motor Engineering & Manufacturing North America, Inc., Plano, TX (US)

(72) Inventors: Taehwa Lee, Ann Arbor, MI (US); Xiaopeng Li, Ann Arbor, MI (US); Ziqi Yu, Ann Arbor, MI (US)

(73) Assignees: Toyota Motor Engineering & Manufacturing North America, Inc., Plano, TX (US); Toyota Jidosha Kabushiki Kaisha, Toyota-shi Aichi-ken (JP)

(21) Appl. No.: 18/883,348

(22) Filed: Sep. 12, 2024

(51) Int. Cl. G01K 11/26; H03H 3/10; H03H 9/02

(52) U.S. Cl. CPC G01K 11/265; H03H 3/10; H03H 9/02834

(57) ABSTRACT

Systems, methods, and other embodiments described herein relate to estimating direction of a surface acoustic wave (SAW) using temperature measurements from multiple resonators. In one embodiment, a method includes measuring temperatures of multiple resonators that are excited by a SAW using a sensor. The method also includes searching an angle from a temperature ratio of the multiple resonators using the temperatures. The method also includes estimating a direction of the SAW using the angle.

### TECHNICAL FIELD

The subject matter described herein relates, in general, to identifying properties of a surface acoustic wave (SAW) using resonators, and, more particularly, to estimating direction of the SAW using temperature measurements made from the resonators.

### BACKGROUND

A surface acoustic wave (SAW) is a wave that propagates along the surface of a material (e.g., a piezoelectric crystal). SAW energy is primarily at a surface layer of the material. Various applications find utility in SAWs due to increased sensitivity and accuracy from the energy existing along the surface layer. A SAW can also be generated as a byproduct from electronic components that communicate signals. Furthermore, in one approach, a SAW is generated and detected through applying an electrical signal to the material. The signal can create mechanical vibrations that travel along the surface for various applications.

In various implementations, systems utilize SAWs in a vehicle for applications such as touch-sensitive controls, monitoring tire pressure, and detecting surface damage. These applications can generate precise and real-time data for enhancing vehicle safety and performance. However, detecting properties of a SAW can be limited by signal attenuation and vibration from a surrounding environment. For instance, a vehicle system generating heat and a controller communicating an electrical signal can degrade the SAW. Similarly, this phenomenon can hinder applications generating a SAW for operation, such as a touch screen. Therefore, systems involving SAW generation and detection encounter difficulties from sources that cause interference.

### SUMMARY

In one embodiment, example systems and methods relate to estimating a direction of a surface acoustic wave (SAW) using temperature measurements from multiple resonators. In various implementations, systems rely upon a SAW for high-frequency filtering and sensing through transducing electrical signals into acoustic waves. For example, a SAW can efficiently propagate along the surface of a piezoelectric substrate without degradation for applications such as touch detection. SAW propagation can also be precisely controlled with components such as resonant frequency filters that are critical for radio frequency (RF) and microwave circuits. However, detecting SAWs can become complex from electronic interference generating SAWs as a byproduct. For instance, circuits generate interference from unintended coupling of electrical signals into acoustic vibrations through rapid changes in voltage and current. Furthermore, sensor applications utilize SAWs where interaction with a medium alters SAW propagation that allows detecting physical features, chemical properties, etc., associated with the medium. Still, inferring details about the properties can be hindered from lacking nuanced features about the SAW. Thus, systems using SAWs for filtering and sensing applications can have certain limitations from circuit interference and extracting diverse properties about materials.

Therefore, in one embodiment, a detection system estimates a direction of a SAW using temperature changes from multiple resonators that are excited by the SAW. Estimating SAW direction allows systems to derive insightful propagation characteristics for detection and sensing applications. In one approach, the multiple resonators are coupled at a subwavelength level through a measured spacing for detecting SAW angles. A SAW can vibrate certain resonators from the multiple resonators at a resonance frequency more than other resonators. Here, the resonance frequency may be proportional to physical dimensions of the certain resonators. Furthermore, the vibration can lead to deformation that causes temperature increases for certain resonators that is measurable through a sensor (e.g., an infrared sensor). The detection system can estimate a direction for the SAW by searching an angle (e.g., 45 degrees) that is normal with the multiple resonators (e.g., two resonators). For instance, the detection system identifies an angle through computing a temperature ratio of the multiple resonators using the temperatures and angular relationships inferred from the measured separation. Therefore, the detection system accurately estimates direction of a SAW for detecting and sensing applications through measuring temperature increases and differences caused by the SAW exciting multiple resonators that correlate with angular directions.

In one embodiment, a detection system for estimating a direction of a SAW using temperature measurements from multiple resonators is disclosed. The detection system includes memory storing instructions, that when executed by a processor, cause the processor to measure temperatures of multiple resonators that are excited by a SAW using a sensor. The instructions also include instructions to search an angle from a temperature ratio of the multiple resonators using the temperatures. The instructions also include instructions to estimate a direction of the SAW using the angle.

In one embodiment, a non-transitory computer-readable medium for estimating a direction of a SAW using temperature measurements from multiple resonators and including instructions that when executed by a processor cause the processor to perform one or more functions is disclosed. The instructions include instructions to measure temperatures of multiple resonators that are excited by a SAW using a sensor. The instructions also include instructions to search an angle from a temperature ratio of the multiple resonators using the temperatures. The instructions also include instructions to estimate a direction of the SAW using the angle.

In one embodiment, a method for estimating a direction of a SAW using temperature measurements from multiple resonators is disclosed. In one embodiment, the method includes measuring temperatures of multiple resonators that are excited by a SAW using a sensor. The method also includes searching an angle from a temperature ratio of the multiple resonators using the temperatures. The method also includes estimating a direction of the SAW using the angle.

### BRIEF DESCRIPTION OF THE DRAWINGS

The accompanying drawings, which are incorporated in and constitute a part of the specification, illustrate various systems, methods, and other embodiments of the disclosure. It will be appreciated that the illustrated element boundaries (e.g., boxes, groups of boxes, or other shapes) in the figures represent one embodiment of the boundaries. In some embodiments, one element may be designed as multiple elements or multiple elements may be designed as one element. In some embodiments, an element shown as an internal component of another element may be implemented as an external component and vice versa. Furthermore, elements may not be drawn to scale.

FIG. 1 illustrates one embodiment of a detection system that is associated with estimating a direction of a SAW using temperature differences measured from exciting multiple resonators.

FIGS. 2A and 2B illustrate embodiments of the detection system of FIG. 1 using a sensor to measure temperature differences among multiple resonators caused by SAW propagation.

FIGS. 3A-3C illustrate examples of various forms, materials, and shapes of using the multiple sensors for estimating a SAW direction.

FIGS. 4A and 4B illustrate examples of energy and response characteristics caused by a SAW deforming resonators.

FIG. 5 illustrates an example of the detection system implemented on a printed circuit board for estimating the direction of a SAW.

FIG. 6 illustrates one embodiment of a method that is associated with searching for an angle from a temperature ratio of the multiple resonators excited by a SAW and estimating direction of the SAW using the angle.

### DETAILED DESCRIPTION

Systems, methods, and other embodiments associated with estimating a direction of a surface acoustic wave (SAW) using temperature measurements and angular relationships from multiple resonators are disclosed herein. In various implementations, systems transmit and receive information with a SAW using an interdigitated transducer (IDT) on a piezoelectric substrate that converts an electrical signal into mechanical vibrations on the surface. The SAW travels across the material surface and another IDT detects the SAW through conversion back into the electrical signal. Similarly, a sensing system can measure environmental changes and structural health from scattering and reflections of a SAW transmitted by an IDT. In another example, electronics generate an unwanted SAW that interferes with system components. The electronics may generate the SAW due to a malfunction, an erroneous byproduct, etc. As such, systems encounter difficulties deriving nuanced properties about the SAW that decrease performance and reliability from various scenarios involving SAWs.

Therefore, in one embodiment, a detection system estimates a propagation direction for a SAW from a source through a sensor measuring a temperature difference caused by the SAW exciting and altering multiple resonators. For example, the temperatures involving a certain group of the multiple resonators increase from deformation energy when near the SAW. Here, the group can form a pattern that together, partially, etc., represent an angle. For instance, a group of two resonators in a circular pattern that has ten resonators energizes at a resonance frequency by the SAW. This can indicate an angle of 36 degrees relative to normal with the two resonators. Meanwhile, the SAW causes decreasing temperatures for other resonators positioned distant from the SAW. In other embodiments, the multiple resonators are two resonators and the SAW deforming one of the resonators indicates a 180° angle. As such, measuring temperature increases and decreases among the multiple resonators using a sensor (e.g., an infrared sensor, an infrared camera, a laser vibrometer, etc.) allows the detection system to observe angular relationships associated with the SAW.

Moreover, in one embodiment, the detection system searches for an angle relative to normal using a temperature ratio of the temperatures measured from the group. In one approach, the temperature ratio increases monotonically away from the resonance frequency of the group beyond a frequency point. This allows the detection system to identify the angular relationships from sensing temperature differences among the multiple resonators. Furthermore, the detection system estimates a direction of the SAW using the angle. For example, the detection system compares temperature ratios between various resonators in a group. As such, the detection system can improve applications receiving the SAW through supplying directional information. For instance, a sensor measuring the structural health of a bridge can locate strong and weak joints through observing the effects from road vibrations generating SAWs. Furthermore, systems can utilize the direction to identify the origin of the SAW when generated from an erroneous source (e.g., malfunctioning electronics). Thus, the detection system improves SAW detection and sensing capabilities through reliably estimating SAW direction using sensed temperature changes caused by altering multiple resonators.

It will be appreciated that for simplicity and clarity of illustration, where appropriate, reference numerals have been repeated among the different figures to indicate corresponding or analogous elements. In addition, the discussion outlines numerous specific details to provide a thorough understanding of the embodiments described herein. Those of skill in the art, however, will understand that the embodiments described herein may be practiced using various combinations of these elements.

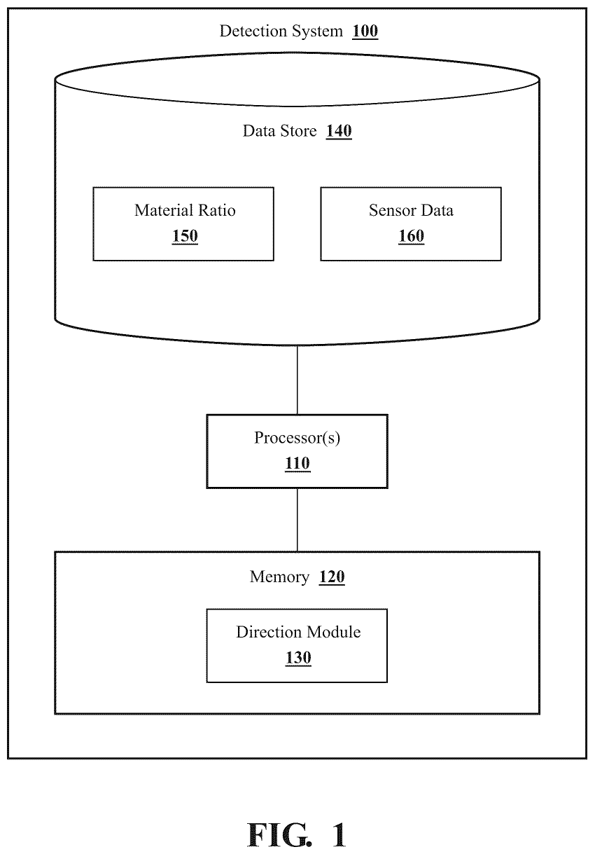

With reference to FIG. 1, in one embodiment, the detection system 100 includes a memory 120 that stores a direction module 130. The memory 120 is a random-access memory (RAM), a read-only memory (ROM), a hard-disk drive, a flash memory, or other suitable memory for storing the direction module 130. The direction module 130 is, for example, computer-readable instructions that when executed by the processor(s) 110 cause the processor(s) 110 to perform the various functions disclosed herein.

The detection system 100 as illustrated in FIG. 1 can be an abstracted form. Moreover, in one embodiment, the detection system 100 includes a data store 140. In one embodiment, the data store 140 is a database. The database is, in one embodiment, an electronic data structure stored in the memory 120 or another data store and that is configured with routines that can be executed by the processor(s) 110 for analyzing stored data, providing stored data, organizing stored data, and so on. Thus, in one embodiment, the data store 140 stores data used by the direction module 130 in executing various functions. In one embodiment, the data store 140 includes the sensor data 160 along with, for example, metadata that characterize various aspects of the sensor data 160. For example, the sensor data 160 includes temperature, heat, etc., measurements for multiple resonators observed by one of an infrared sensor, an infrared camera, a laser vibrometer, a transducer, and an interferometer. In one embodiment, the data store 140 further includes a material ratio 150 having information about angles associated with different temperature ratios observed among or between multiple resonators.

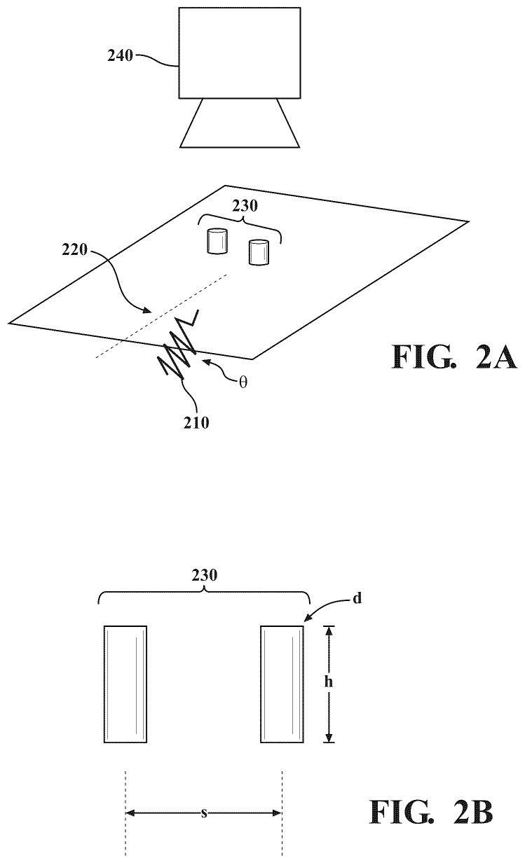

Now turning to FIGS. 2A and 2B, embodiments of the detection system 100 of FIG. 1 using a sensor (e.g., an infrared camera) to measure temperature differences among multiple resonators caused by SAW propagation are illustrated. In various implementations, the detection system 100 and the direction module 130 include instructions that cause the processor 110 to measure temperatures of multiple resonators that are excited by a SAW using the sensor 240. A SAW source can be one of piezoelectric signal generator, a frequency oscillator, a signal filter, and malfunctioning electronics. A SAW can exhibit frequencies, frequency components, center frequencies, etc., ranging from a few Megahertz to multiple Gigahertz. For instance, a SAW originates from electronic components interfering with electromagnetic radiation, such as a byproduct signal. The detection system 100 can search an angle from a temperature ratio of the multiple resonators using the temperatures. In one approach, the direction module 130 estimates a direction of the SAW using the angle. Estimating the direction for the SAW allows for deriving useful information about electric components, such as accuracy for signal generators. SAW direction can also identify abnormal SAW generation, leakage, etc., for monitoring the structural health of electric components.

FIG. 2A illustrates the detection system 100 estimating angle θ of SAW 210 traveling through one of a printed circuit board (PCB), silicon, lithium niobate, etc., medium. Here, two resonators 230 can be separated by a subwavelength distance on a substrate, plate, etc., associated with the SAW 210 and the angle θ is relative to a normal 220 between the two resonators 230 having similar resonant frequencies. Although FIG. 2A illustrates an implementation involving the two resonators 230, any number of resonators can detect the direction of the SAW 210 that have similar resonant frequencies as further explained below. One of the two resonators 230 can respond differently than the other from proximity with the SAW 210. This causes a difference in vibration amplitudes and a corresponding temperature difference. Furthermore, the detection system 100 can utilize other directional representations besides the angle θ for the SAW 210. In one approach, the detection system 100 estimates from one of two resonators 230 being excited at a resonant frequency and a temperature ratio between the two resonators 230 that the direction of the SAW 210 is 180°. On the contrary, the detection system 100 estimates from another of the two resonators 230 being excited at a different resonant frequency and a temperature ratio between the two resonators 230 that the direction of the SAW 210 is −180°. In this way, the detection system 100 can derive a direction for the SAW 210 from temperature differences and angular relationships between the two resonators 230.

In various implementations, FIG. 2B illustrates that the two resonators 230 are mechanical resonators forming cylindrical pillars. In one approach, the two resonators 230 are a solid material for sensing SAWs and separated by distance s having a height h and diameter d. As further explained below, the sensor 240 is one of an infrared sensor, an infrared camera, a laser vibrometer, a transducer, and an interferometer that monitors a temperature of the two resonators 230. For instance, the SAW 210 propagates along the surface and excites one of the two resonators 230 that causes a temperature difference from the vibration energy between the two resonators 230. Here, the vibration energy in a resonator varies depending upon the orientation of the SAW 210, a resonant frequency of the resonator, and the frequencies of the SAW 210. Such a variation in temperature can be correlated to the angle θ and actual direction of the SAW 210.

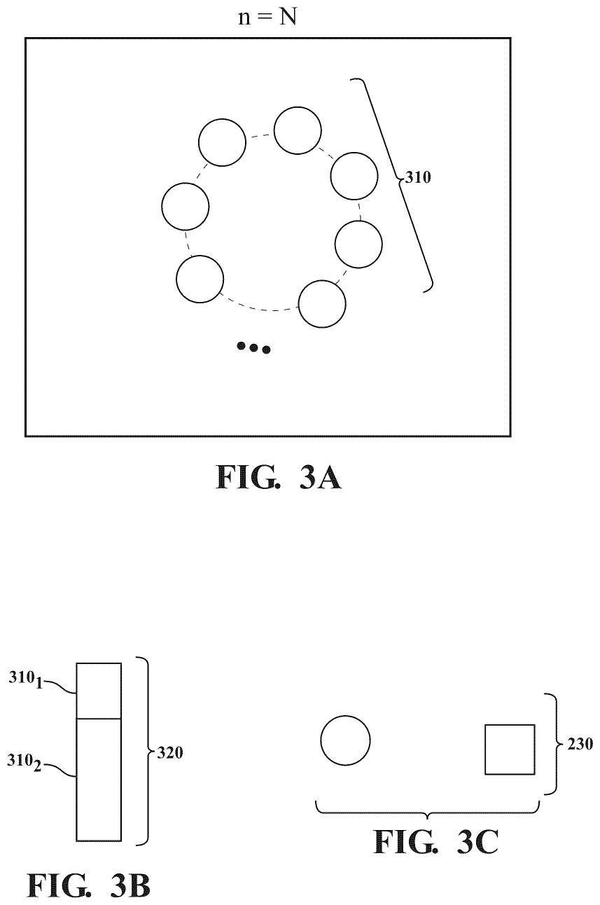

Regarding additional configurations for the two resonators 230, FIGS. 3A-3C illustrate examples of various forms, materials, and shapes of using the multiple sensors for estimating SAW direction. Here, a number of resonators, resonator materials, resonator types, resonator shapes, etc., can vary. In FIG. 3A, the detection system 100 can utilize n=3 . . . N of multiple resonators 310 in a circular form, pattern, etc. For example, one of the multiple resonators 310 can detect 10 degrees when N is 36. The multiple resonators 310 can be separated by one or more wavelengths, a subwavelength, etc., associated with the SAW 210 for detection. In another example, the direction module 130 estimate a direction when the SAW 210 excites and deforms a subset of the multiple resonators 310 while other resonators having similar resonant frequencies are less affected. This can indicate that the subset of the multiple resonators 310 detect certain frequencies of the SAW 210 that causes resonance and temperature differences, such as frequencies that stress electronic components. As such, the detection system 100 having the multiple resonators 310 can detect direction of the SAW 210 with increased sensitivity through the sensor 240 acquiring more data through covering degree areas more granularly.

Regarding FIGS. 3B and 3C, multiple resonators 320 illustrate having different materials that are stacked and form a pillar, micropillar, etc. In FIG. 3B, the multiple resonators 320 include material 310₁ that can have a composition which is stiffer and more rigid than the resonator 310₂. As such, the multiple resonators 320 exhibit a different resonant frequency and bandwidth from having a heterogenous composition compared with a homogenous form. For instance, the resonant frequency is reduced from the material 310₁ being polydimethylsiloxane (PDMS) that exhibits a stiff and rigid form for resonance. In another example, the multiple resonators 320 are cylindrical pillars having a bottom portion comprising silicon and a top portion made with the PDMS. In this way, the multiple resonators 320 can be purpose-built to tune into different SAWs. Furthermore, FIG. 3C exhibits the two resonators 230 comprising a cylindrical form and a square form. The mixed structure and form allows detecting the SAW 210 at a particular resonant frequency and a bandwidth frequency since physical form impacts resonance properties.

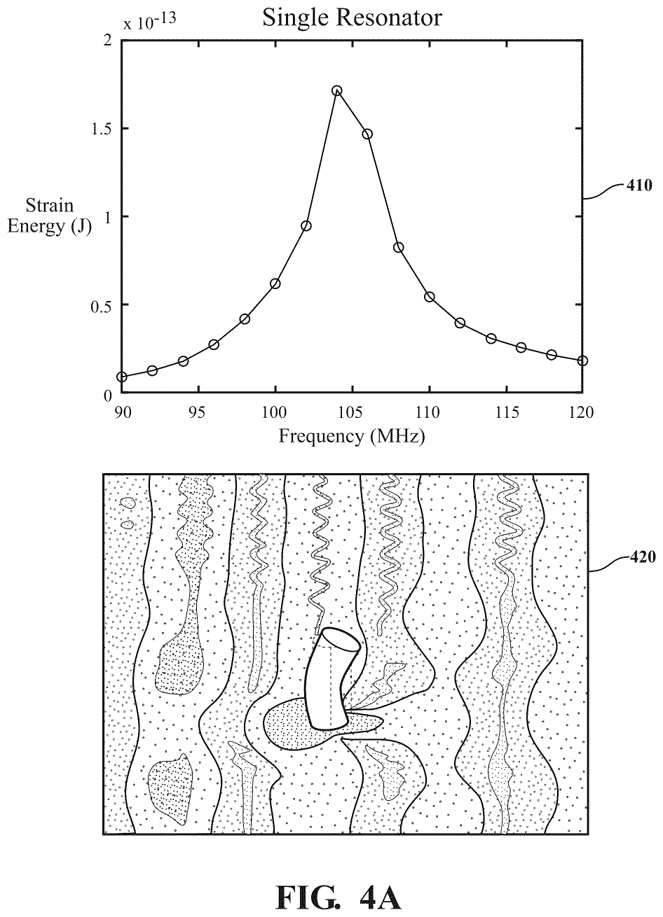

Now referring to FIGS. 4A and 4B, examples of energy and frequency response characteristics caused by a SAW deforming resonators are illustrated. Chart 410 illustrates strain energy, deformation energy, etc., in Joules (J) storable among one of the multiple resonators 310. Here, the energy varies over different frequencies when excited by the SAW 210. For example, one of the multiple resonators 310 is a cylindrical micropillar having sizes h=10 micrometers (μm) and d=4 μm that resonates around 105 Megahertz (MHz). Adjusting values for h and d can tune the two resonators 230 to sense the angle θ involving varying frequencies, energy levels, etc., of the SAW 210.

In FIG. 4A, a heat map 420 illustrates the multiple resonators 310 experiencing bending, deformation, disfiguration, etc., at various resonant frequencies. Here, first and second subsets of the multiple resonators 310 can have similar resonant frequencies. The first subset from the multiple resonators 310 experiences temperature increases through deformation energy, vibration energy, strain energy, etc., caused by the SAW 210 at or near a resonant frequency. Such an increase measured by the sensor 240 indicates an θ₁ associated with a direction for the SAW 210. Furthermore, decreasing temperatures of a second subset from the multiple resonators 310 by the SAW can negate an angle θ₂ for the SAW 210. This observation can be from the SAW 210 traveling towards the first subset rather than the second subset. As such, temperatures are correlated with angular relationships and the SAW 210 aligns with a direction for the first subset rather than a second direction about the second subset.

In another example, the detection system 100 observes a bend increase for the multiple resonators 310 at a resonance frequency caused by the SAW 210. Here, the resonance frequency can be associated with a height and a diameter of the multiple resonators 310. FIG. 4B indicates the relationship between a SAW angle and strain energy for the multiple resonators 310. Here, the multiple resonators 310 can have h=10 μm, d=4 μm, and s=3 μm and a SAW frequency 109 MHz. In one approach, one of the two resonators 230 more proximate with the incoming SAW 210 experiences increasing strain energy while the other one of the two resonators 230 has decreasing strain energy. Here, the strain energy can associated with an incident angle θ deviating from the normal 220 relative to the two resonators 230. Chart 430 illustrates the strain energy varying for pillars 1 and 2 representing the two resonators 230. As previously described, strain energy is proportional to temperature increase for pillars 1 and 2. Chart 440 illustrates that the strain ratio between the two resonators 230 can be used to estimate a SAW direction through angular relationships that are correlated with temperature increases.

Moreover, a temperature ratio computed with measurements from the multiple resonators 310 using the sensor 240 can vary as follows. The temperature ratio can increase with angle from excitation by the SAW 210 between a resonator A and a resonator B as represented with T_{B}/T_{A.} However, the temperature ratio can also decrease as a frequency associated with the SAW 210 moves away from the resonance frequency (e.g., 109 MHz). Here, the detection system 100 may observe a one-to-one correspondence for direction estimates involving angle versus strain ratios for frequencies higher than the resonance frequency. Such a one-to-one correspondence can be absent for lower frequencies and certain angles (e.g., −90°, +90°, etc.) while observable at limited angles (e.g., −60°, +60°, etc.). As such, strain differences between the multiple resonators 310 can lead to related temperature differences measured by the sensor 240. For sensitive direction estimates, SAW frequencies that are close to resonance frequencies but higher than the resonance frequency exhibit a one-to-one correspondence.

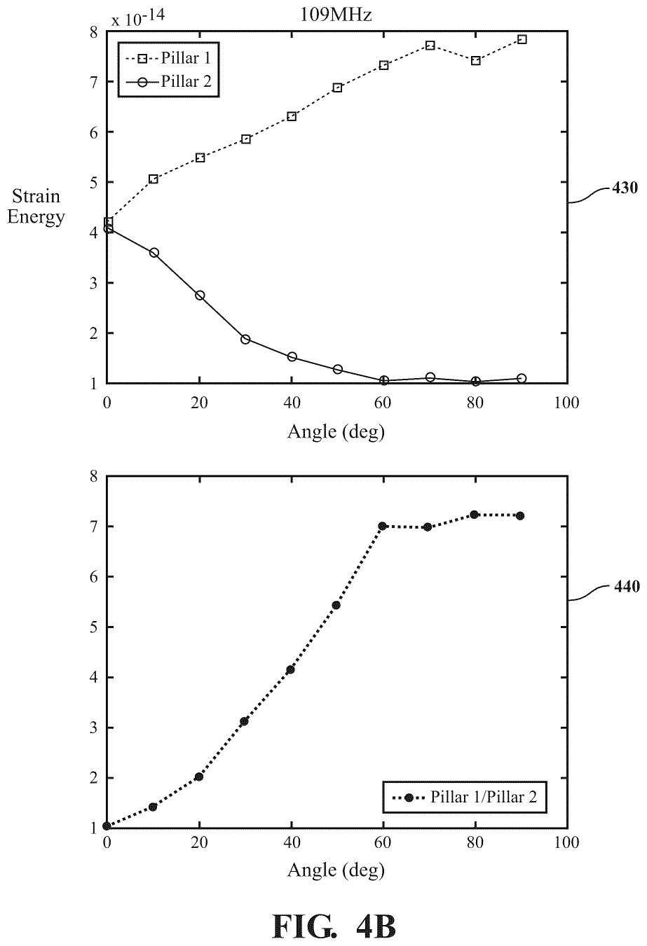

Now turning to FIG. 5, an example of the detection system 100 implemented on a PCB 510 for estimating the direction of the SAW 210 is illustrated. Here, the SAW 210 propagates on a substrate forming the PCB 510 and the PCB 510 includes electronic components. In one approach, the electronic components generate the SAW 210 as a byproduct and the SAW 210 propagates towards the two resonators 230. Furthermore, the sensor 240 is positioned on or near the PCB 510 for monitoring temperature changes and differences among the two resonators 230 caused by resonant vibrations involving the SAW 210. The detection system 100 can search an angle using a temperature ratio computed with temperatures measured for the two resonators 230. For example, a table lists temperatures at resonant frequencies for various resonators according to one of shape, size, material composition, etc. In this way, the direction module 130 can estimate a direction of the SAW 210 using the angle relative to a normal for the two resonators 230.

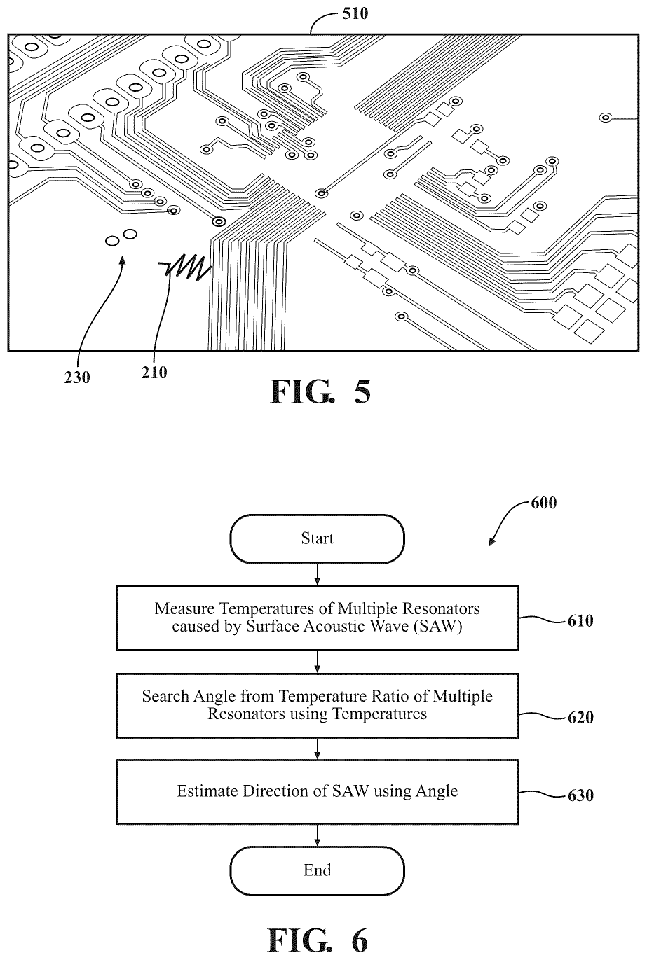

Turning to FIG. 6, one embodiment of a method 600 that is associated with searching for an angle from a temperature ratio of multiple resonators excited by a SAW and estimating SAW direction using the angle is illustrated. Method 600 will be discussed from the perspective of the detection system 100 of FIG. 1. While the method 600 is discussed in combination with the detection system 100, it should be appreciated that the method 600 is not limited to being implemented within the detection system 100 but is instead one example of a system that may implement the method 600.

At 610, the detection system 100 has a sensor that measures temperature changes of multiple resonators caused by an excitation from a SAW. Here, the sensor may be one of an infrared sensor, an infrared camera, a laser vibrometer, a transducer, and an interferometer that monitors and measures temperature differences among multiple resonators. The temperature changes can be caused by the SAW propagating through a medium. As previously explained, the SAW can originate from one of piezoelectric signal generator, a frequency oscillator, a signal filter, and malfunctioning electronics. A number of resonators, resonator materials, resonator types, resonator shapes, etc., vary among the multiple resonators depending upon SAW types. Furthermore, as the SAW propagates along a device surface, vibration energy from the SAW causes a temperature increase and differences among one or more of the multiple resonators. For instance, the vibration from the SAW causes deformation, bending, etc., at a resonant frequency associated with one or more the resonators. The physical changes by a resonator from vibration energy can vary depending upon the orientation of the SAW. As such, the detection system 100 can correlate varying temperatures with angle θ and direction of the SAW.

At 620, the detection system 100 searches for an angle from a temperature ratio of the multiple resonators computed using the temperatures measured with the sensor. As previously explained, a temperature ratio computed with temperatures measured from two, a subset, etc., of the multiple resonators can increase with angle caused by vibration energy from the SAW. For example, a temperature ratio between a resonator A and a resonator B can be represented as T_{B}/T_{A}. Here, the temperature ratio may decrease as a frequency associated with the SAW moves away from the resonance frequency and certain resonators. In one approach. SAW frequencies that are close to resonance frequencies but higher than the resonance frequency regularly exhibit a one-to-one correspondence, thereby allowing correlation inferences between measured temperature and angular relationships that are accurate. Furthermore, the detection system 100 can identify an angle through searching using a table. For instance, the table lists temperatures at resonant frequencies for the multiple resonators according to one of a shape, a size, a material composition, etc.

At 630, the direction module 130 estimates the direction of the SAW using the angle. For example, a resonator configuration includes six resonators that divide a sensing area into 60° sections. Here, the SAW causes a measured rise in a temperature ratio between a first resonator pair from increasing a vibration energy through resonance. The temperature ratio may indicate that the SAW is moving away from the first resonator pair at an angle of 120° relative to a normal between the SAW and the first resonator pair. Another temperature ratio indicates that the SAW is moving toward a second resonator pair position at angle of 180° from a relative normal between the SAW and the second resonator pair. As such, the detection system 100 and the direction module 130 estimate a direction of the SAW at 180°. The direction module 130 may also estimate direction for the SAW as −60° relative to the second resonator pair.

In another approach, the direction module 130 estimates a direction when the SAW 210 excites a subset of the multiple resonators through deformation energy while other resonators are less affected. This can indicate that the subset of the multiple resonators detect certain frequencies of the SAW that cause resonance, such as frequencies that stress electronic components. Accordingly, the detection system 100 reliably estimates SAW direction using sensed temperature changes and computed temperature ratios that are correlated with angles when deforming multiple resonators.

Detailed embodiments are disclosed herein. However, it is to be understood that the disclosed embodiments are intended as examples. Therefore, specific structural and functional details disclosed herein are not to be interpreted as limiting, but merely as a basis for the claims and as a representative basis for teaching one skilled in the art to variously employ the aspects herein in virtually any appropriately detailed structure. Furthermore, the terms and phrases used herein are not intended to be limiting but rather to provide an understandable description of possible implementations. Various embodiments are shown in FIGS. 1-6, but the embodiments are not limited to the illustrated structure or application.

The flowcharts and block diagrams in the figures illustrate the architecture, functionality, and operation of possible implementations of systems, methods, and computer program products according to various embodiments. In this regard, a block in the flowcharts or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved.

The systems, components, and/or processes described above can be realized in hardware or a combination of hardware and software and can be realized in a centralized fashion in one processing system or in a distributed fashion where different elements are spread across several interconnected processing systems. Any kind of processing system or another apparatus adapted for carrying out the methods described herein is suited. A typical combination of hardware and software can be a processing system with computer-usable program code that, when being loaded and executed, controls the processing system such that it carries out the methods described herein

The systems, components, and/or processes also can be embedded in a computer-readable storage, such as a computer program product or other data programs storage device, readable by a machine, tangibly embodying a program of instructions executable by the machine to perform methods and processes described herein. These elements also can be embedded in an application product which comprises the features enabling the implementation of the methods described herein and, which when loaded in a processing system, is able to carry out these methods.

Furthermore, arrangements described herein may take the form of a computer program product embodied in one or more computer-readable media having computer-readable program code embodied, e.g., stored, thereon. Any combination of one or more computer-readable media may be utilized. The computer-readable medium may be a computer-readable signal medium or a computer-readable storage medium. The phrase “computer-readable storage medium” means a non-transitory storage medium. A computer-readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer-readable storage medium would include the following: a portable computer diskette, a hard disk drive (HDD), a solid-state drive (SSD), a ROM, an EPROM or flash memory, a portable compact disc read-only memory (CD-ROM), a digital versatile disc (DVD), an optical storage device, a magnetic storage device, or any suitable combination of the foregoing. In the context of this document, a computer-readable storage medium may be any tangible medium that can contain, or store a program for use by or in connection with an instruction execution system, apparatus, or device.

Generally, modules as used herein include routines, programs, objects, components, data structures, and so on that perform particular tasks or implement particular data types. In further aspects, a memory generally stores the noted modules. The memory associated with a module may be a buffer or cache embedded within a processor, a RAM, a ROM, a flash memory, or another suitable electronic storage medium. In still further aspects, a module as envisioned by the present disclosure is implemented as an ASIC, a hardware component of a system on a chip (SoC), as a programmable logic array (PLA), or as another suitable hardware component that is embedded with a defined configuration set (e.g., instructions) for performing the disclosed functions.

Program code embodied on a computer-readable medium may be transmitted using any appropriate medium, including but not limited to wireless, wireline, optical fiber, cable, radio frequency (RF), etc., or any suitable combination of the foregoing. Computer program code for carrying out operations for aspects of the present arrangements may be written in any combination of one or more programming languages, including an object-oriented programming language such as Java™, Smalltalk™, C++, or the like and conventional procedural programming languages, such as the “C” programming language or similar programming languages. The program code may execute entirely on the user's computer, partly on the user's computer, as a stand-alone software package, partly on the user's computer and partly on a remote computer, or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

The terms “a” and “an,” as used herein, are defined as one or more than one. The term “plurality,” as used herein, is defined as two or more than two. The term “another,” as used herein, is defined as at least a second or more. The terms “including” and/or “having,” as used herein, are defined as comprising (i.e., open language). The phrase “at least one of . . . and . . . ” as used herein refers to and encompasses any and all combinations of one or more of the associated listed items. As an example, the phrase “at least one of A, B, and C” includes A, B, C, or any combination thereof (e.g., AB, AC, BC, or ABC).

Aspects herein can be embodied in other forms without departing from the spirit or essential attributes thereof. Accordingly, reference should be made to the following claims, rather than to the foregoing specification, as indicating the scope hereof.

What is claimed is:

1. A detection system comprising:
a memory storing instructions that, when executed by a processor, cause the processor to:
measure temperatures of multiple resonators that are excited by a surface acoustic wave (SAW) using a sensor;
search an angle from a temperature ratio of the multiple resonators using the temperatures; and
estimate a direction of the SAW using the angle.

2. The detection system of claim 1 further including instructions to:
sense an increase in the temperatures of a first subset from the multiple resonators through deformation energy from the SAW; and
sense a decrease in the temperatures of a second subset from the multiple resonators by strain energy from the SAW, wherein the temperatures are correlated with the angle and the SAW aligns to a first direction about the first subset rather than a second direction about the second subset.

3. The detection system of claim 1 further including instructions to:
observe a bend of the multiple resonators from a heat increase at a resonance frequency caused by the SAW, the resonance frequency associated with a height and a diameter of the multiple resonators.

4. The detection system of claim 1, wherein:
the multiple resonators form a circular pattern separated by a wavelength associated with the SAW, the multiple resonators are a solid material; and
the multiple resonators are thirty-six resonators that sense ten-degree areas.

5. The detection system of claim 1, wherein the temperature ratio increases monotonically away from a resonance frequency of the multiple resonators.

6. The detection system of claim 1, wherein the multiple resonators are cylindrical pillars having a bottom portion comprising silicon and a top portion comprising polydimethylsiloxane (PDMS).

7. The detection system of claim 1, wherein the multiple resonators are two resonators on a substrate separated by a subwavelength and the two resonators comprise different materials that are stacked and form a pillar.

8. The detection system of claim 1, wherein a source of the SAW is one of a piezoelectric signal generator, a frequency oscillator, a signal filter, and malfunctioning electronics.

9. The detection system of claim 1, wherein the sensor is one of an infrared sensor, an infrared camera, a laser vibrometer, a transducer, and an interferometer.

10. A non-transitory computer-readable medium comprising:
instructions that when executed by a processor cause the processor to:
measure temperatures of multiple resonators that are excited by a surface acoustic wave (SAW) using a sensor;
search an angle from a temperature ratio of the multiple resonators using the temperatures; and
estimate a direction of the SAW using the angle.

11. The non-transitory computer-readable medium of claim 10 further including instructions to:
sense an increase in the temperatures of a first subset from the multiple resonators through deformation energy from the SAW; and
sense a decrease in the temperatures of a second subset from the multiple resonators by strain energy from the SAW, wherein the temperatures are correlated with the angle and the SAW aligns to a first direction about the first subset rather than a second direction about the second subset.

12. A method comprising:
measuring temperatures of multiple resonators that are excited by a surface acoustic wave (SAW) using a sensor;
searching an angle from a temperature ratio of the multiple resonators using the temperatures; and
estimating a direction of the SAW using the angle.

13. The method of claim 12 further comprising:
sensing an increase in the temperatures of a first subset from the multiple resonators through deformation energy from the SAW; and
sensing a decrease in the temperatures of a second subset from the multiple resonators by strain energy from the SAW, wherein the temperatures are correlated with the angle and the SAW aligns to a first direction about the first subset rather than a second direction about the second subset.

14. The method of claim 12 further comprising:
observing a bend of the multiple resonators from a heat increase at a resonance frequency caused by the SAW, the resonance frequency associated with a height and a diameter of the multiple resonators.

15. The method of claim 12 further comprising:
forming the multiple resonators into a circular pattern separated by a wavelength associated with the SAW, the multiple resonators are a solid material; and
the multiple resonators are thirty-six resonators that sense ten-degree areas.

16. The method of claim 12, wherein the temperature ratio increases monotonically away from a resonance frequency of the multiple resonators.

17. The method of claim 12, wherein the multiple resonators are cylindrical pillars having a bottom portion comprising silicon and a top portion comprising polydimethylsiloxane (PDMS).

18. The method of claim 12, wherein the multiple resonators are two resonators on a substrate separated by a subwavelength and the two resonators comprise different materials that are stacked and form a pillar.

19. The method of claim 12, wherein a source of the SAW is one of a piezoelectric signal generator, a frequency oscillator, a signal filter, and malfunctioning electronics.

20. The method of claim 12, wherein the sensor is one of an infrared sensor, an infrared camera, a laser vibrometer, a transducer, and an interferometer.
